(19) United States
(12) Patent Application Publication
(10) Pub. No.: US 2024/0164199 A1
(43) Pub. Date: May 16, 2024

(54) METHOD OF TRANSFER OF ORGANIC SEMICONDUCTOR FILMS TO A SUBSTRATE AND ELECTRONIC DEVICES MADE THEREFROM

(71) Applicant: FRIEDRICH-SCHILLER-UNIVERSITÄT JENA, Jena (DE)

(72) Inventors: Sirri Batuhan KALKAN, Munich (DE); Bert NICKEL, Munich (DE); Antony GEORGE, Jena (DE); Andrey TURCHANIN, Jena (DE)

(21) Appl. No.: 18/551,659

(22) PCT Filed: Mar. 21, 2022
(86) PCT No.: PCT/EP2022/057304

§ 371 Date: Sep. 21, 2023

(30) Foreign Application Priority Data
Mar. 22, 2021 (DE) 10 2021 107 057.0

(51) Int. Cl. H10K 71/00; H10K 71/10

(52) U.S. Cl. CPC H10K 71/621; H10K 71/10

(57) ABSTRACT

A method of transferring a semiconductor film (120) from a first substrate (100) to a target substrate (170) is disclosed. The method comprises coating (210) a water-soluble thin film (110) onto the first substrate (100), growing (220) a layer of the semi-conductor film (120) onto the water-soluble thin film (100), placing (230) the water-soluble thin film (110) in contact with water (130) to enable dissolution of the water-soluble thin film (110), floating (250) the semiconductor film (120) on a meniscus (155) of water, placing one end of the floating semiconductor film (120) in contact with the target substrate (170), and passing (280) the target substrate (170) through the meniscus at an angle.

### FIELD OF THE INVENTION

This application claims priority of the German Patent Application number DE10 2021 107 057.0, filed on 22 Mar. 2021. The entire disclosure of the German Patent Application number DE10 2021 107 057.0 is hereby incorporated herein by reference.

The invention relates to a method of transfer of organic semiconductor films to a substrate and electronic devices made therefrom.

### CROSS-REFERENCE TO RELATED APPLICATIONS

None

### BACKGROUND OF THE INVENTION

It is known that small molecule organic semiconductors (OSC) combine hole transport^{1,2} with tunable optoelectronic properties^{3,4}. Transition metal dichalcogenides (TMDs) are a non-limiting example of materials that show electron transport^{5,6}. A proper interfacing of the TMDs with the OSC enables the combination of the unipolar nature of both of the materials to form ambipolar structures. However, experience has shown that a well-defined heterojunction of highly ordered OSC films on the TMDs by evaporation of small molecules is extremely difficult to achieve due to suppressed key nucleation processes, such as molecular diffusion and aggregation⁷.

Another method for the creation of the heterojunction of the OSC film on the TMD is a transfer of the OSC films onto the TMD layer. Materials from which the OSCs are made fall into two main classes. The first class comprises polymers which are disordered or semicrystalline materials. The second class comprise crystalline small molecule OSC materials. These crystalline small molecular OSC materials are more difficult to transfer but enable higher performance⁹.

Commercial organic semiconductor products, such as AMOLED displays, employ small molecule crystalline OSC to benefit from the excellent optoelectronic properties of the OSCs which are able to outperform inorganic semiconductors¹⁰. The hole transport mobilities of the crystalline OSC materials match and exceed those of amorphous Si¹¹. In field effect geometries this hole transport is confined to an interfacial layer having a thickness of a few nanometers.

An organic-inorganic heterojunction device combines optical properties of organic semiconductors and hole transport with high electron mobilities of 2D materials¹²⁻¹⁴. As noted above, the crystalline growth of the small molecules on metallic and semiconducting interfaces is notoriously difficult^{15,16}. Surface modification techniques such as self-assembled monolayers (SAM) are needed prior to growth¹⁷. However, for the construction of an atomically abrupt semiconductor heterojunction for the organic-inorganic heterojunction device, such thiol- silane- or phosphonate SAMs are not an option.

Experiments with hybrid heterostructures for FETs^{7,18-21} and optical transitions²² have in the past all suffered from low crystallinity and reduced transport in the organic part of the heterojunction device. One way to overcome this bottleneck is to transfer single crystals of the OSCs on top of the 2D materials. This was demonstrated for ambipolar and anti-ambipolar transistors used as gate tunable rectifiers^{8,23,24}. However, the single crystal OSCs of this prior art are not compatible with wafer scale processing technologies. Moreover, the films of the OSC crystals exhibit large grains of several microns approaching the size of TMD flakes and triangles.

### SUMMARY OF THE INVENTION

This document teaches a novel water droplet meniscus-based transfer method for transferring OSC films onto a substrate. The OSC films are evaporated on polyacrylic acid (PAA) templates on 2-inch (5.08 cm) wafers. The PAA is dissolved in a controlled geometry with help of a water meniscus to form 2-inch disks made of the OSC films. The 2-inch OSC disks can be removed and transferred to the substrates. The large crystalline grains of the OSC and their optical anisotropy are conserved by this method.

It is possible using this method to fabricate ambipolar and anti-ambipolar field effect transistors (FETs) onto a substrate of molybdenum disulfide (MoS₂) that challenge single crystal OSC results⁸. This shows the potential of transferred OSC nanosheets for flexible electronic and optoelectronic devices.

The transfer preserves substantially the crystallinity and morphology of the OSC films. The method outlined in this document enables the fabrication of the unipolar FET device which outperform conventional bottom contact devices. Fabrication of ambipolar devices with TMD materials is possible and such devices reach the performance of heterojunction devices build from organic single crystals. The transfer was demonstrated up to 3″ (7.62 cm) wafer scale and can be used for the fabrication of opto-electronic hybrid devices.

### DESCRIPTION OF THE DRAWINGS

FIGS. 1A-1G shows an illustration of the method of transfer of the film.

FIG. 2 shows an outline of the method.

FIG. 3 shows a bottom-contact, bottom-gate organic FET in inverted coplanar geometry.

FIG. 4 shows a hybrid heterojunction device.

### DETAILED DESCRIPTION OF THE INVENTION

The invention will now be described on the basis of the drawings. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention.

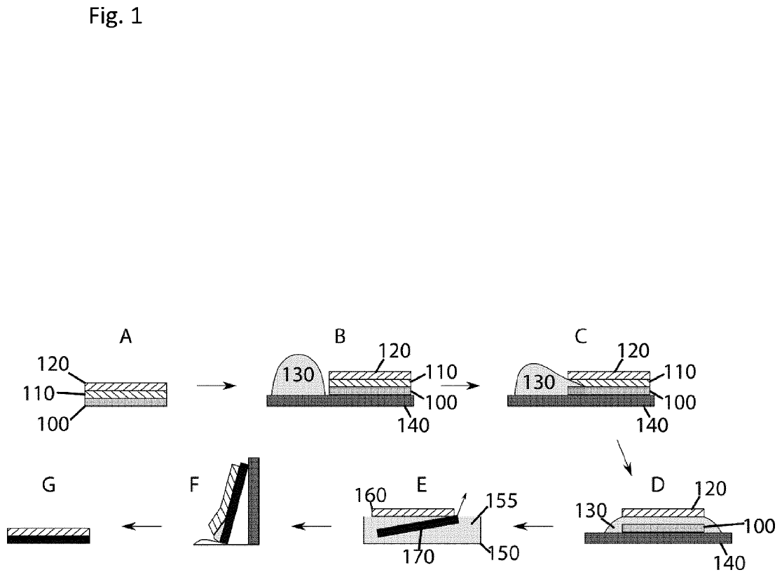

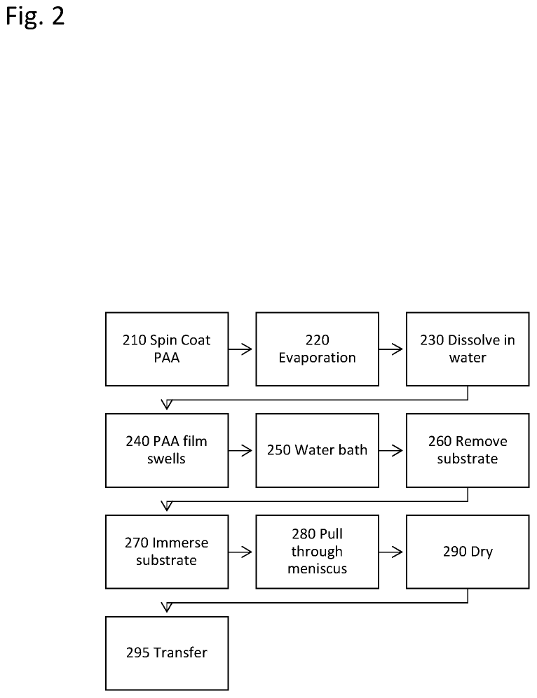

This document teaches a transfer technique for transferring hydrophobic film with a low molecular weight (under 1000 Daltons) to a substrate. FIG. 1 shows one aspect of this transfer and this is described in FIG. 2. In a first step 210, a water-soluble thin film 110 is spin coated on a substrate 100. In one aspect, a polyacrylic acid (PAA) thin film was used. Other alternative materials include, but are not limited to, poly(sodium-4-styrene sulfonate) (PSSNa) thin film, or a polyvinyl alcohol (PVA) thin film.

The substrate 100 is, for example, a microscope cover glass or a silicon wafer but this is not limiting of the invention, and will be generally hydrophilic. The PAA thin film 100 acts as a growth template for the organic semiconductor film 120 by evaporation in step 220. In one aspect of the invention, a pentacene or dinaphtho[2,3-b:2′,3′-f]thieno[3,2-b]thiophene (DNTT) organic thin film 120 is grown on the PAA thin film, but it will be appreciated that this is not limiting of the invention and other semiconductor films can be grown. For example, the thin film 100 could also be a fullerene, e.g., C₆₀. It is also possible to use functionalized semiconductor films and films made of derivatives of an organic semiconductor, such as derivatives of DNTT. Derivatives of DNTT include, but are not limited to, DPh-DNTT (diphenyl-dinaphtho[2,3-b:2′,3′-f]thieno[3,2-b]thiophene) and Cn-DNTT (n=6,8,10,12) (Alkylated Dinaphtho[2,3-b:2′,3′-f]thieno[3,2-b]thiophenes)

In the following step 230, the PAA thin film 110 is dissolved in water. This can be done in several ways. In a first method, the PAA thin film 110 with the OSC film 120 was immersed slowly in a water bath of deionized (DI) water at a shallow angle and the OSC film 120 separated onto the meniscus of the DI water bath upon dissolution of the PAA thin film 110. This technique was found to work well for a nanosheet of pentacene film due to its high elastic modulus, but in case of the nanosheet of DNTT film, it was found that the OSC film 120 of DNTT ends up with broken pieces (elastic modulus of 16.09 GPa for pentacene whereas the elastic modulus is 2.3 GPa for DNTT).

A second method was a “dropping substrate” method in which the substrate with the PAA thin film 110 and the OSC film 120 is dropped from a fixed height onto the meniscus of the water bath. The PAA tends to be dehydrated and thus the substrate can float on the meniscus. However, the PAA thin film 110 is forced to absorb water by the impact and thus the dissolving of the PAA thin film 110 starts (step 230). The substrate attempts to sink into the water bath at edges where parts of the PAA thin film 110 have already been dissolved. Therefore, as the PAA thin film 110 is dissolved, the area of the PAA thin film 110 that is resistant to sink becomes smaller and the weight of the sunk part increases. This contradiction increases the stress on the OSC film 120 until the dissolving of the PAA thin film 110 is completed. If the PAA thin film 110 can no longer lift the substrate anymore, the substrate sinks by pulling the nanosheet of the OSC film 120 off from its center. Depending on the weight of the substrate, this off-center pulling may occur towards to the end of the dissolving or even in the beginning of the dissolving. Therefore, in the dropping meniscus method, the surface tension gradient driving force is replaced with the impact force (because if substrate is dropped from 1 cm to 2 cm above the meniscus dissolving does not occur) and the sunk weight of the substrate replaces an advancing contact angle, as discussed below in connection with FIG. 1.

Another method for the removal of the OSC film 120 is the passage of the substrate 100 covered with the PAA thin film 110 and the OSC film 120 slowly through a water meniscus. This is found to improves the release of the PAA thin film somewhat, but the size of the organic film flakes of the OSC film 120 swimming on the water surface of the water bath remains rather small and is typically of the order of a few millimeters, even in most careful handling.

In the prior art, it has been observed that this fractioning of the OSC film 120 can be suppressed by crosslinking of the OSC film 120 by gentle low energy e-beam exposure. This crosslinking converts the surface region of the OSC film 120 into a covalently linked amorphous carbon-like region and the cross-linking through exposure to the e-beam is not beneficial in the context of the heterojunction devices.

A further method for the transfer is shown in FIG. 1 in which a water droplet 130 is placed on a moderately hydrophobic glass slide 140 next to a sample. The sample (FIG. 1A) of the substrate 100, the PAA thin film 100 and the OSC film 120 is placed on the same glass slide 140 and is brought into side contact with the water droplet 140 at a contact angle of 50°, as is shown in FIG. 1B. The PAA thin film 110 swells in step 240 and is dissolved in a controlled manner from one side of the sample as shown in FIG. 1C. The hydrophobic organic nanosheet²⁵ of the OSC film 120 floats on the meniscus of the water droplet 130, as is expected from surface energy arguments. This floating is shown in FIG. 1D. It was found in an unexpected matter that it was possible to drive this release process of the OSC film 120 from the PAA thin film 110 without disrupting the structure of the nanosheet of the OSC film 120 by adding more water to the water droplet 120 from a syringe (not shown).

In another aspect of the invention, a stream of water impacts on the side of the PAA thin film 110 to dissolve the PAA thin film. This stream of water could come from a syringe or through a tube from a pump (not shown).

It is subsequently possible to release the whole (2″ to 3″—5.08 cm to 7.62 cm) nanosheet floating freely on the surface of water by placing the substrate 100 with the OSC film 120 and the water droplet 130 in a water bath 150 in step 250 and then removing the substrate 100 from the water bath 150, as is shown in FIG. 1E. The OSC film 120 is only 50 nm thick, but the whole process from steps 230-260 can be followed by eye inspection due to subtle changes of the substrate 100 and water surface reflectance in the water bath 150.

Wetting phenomena are responsible for this release mechanism of the OSC film 120. The contact angle of water with the bare sample substrate 100 after plasma treatment of the bare sample substrate 100 is small, i.e., about 7° and after deposition of the PAA film 110 is about 12°. The surface tension gradient between the moderately hydrophobic glass slide 140 and the PAA thin film 110 creates a net driving force towards the hydrophilic side²⁶ as can be seen in FIGS. 1B and 1C. The PAA thin film 110 is dissolved. The driving force is adjusted by the amount of water added to the water droplet 130. This control is missing in the other release methods discussed above which use conventional passage of the substrate through the meniscus. It was determined that the lack of such control induces cracks in the nanosheet of the OSC film 120 due to steep bending at the interface, as noted above. In particular it will be appreciated that the small contact angle enables the thin film 110 to easily “float off” the substrate 100 with no sharp curvature to induce defects into the thin film 110.

The high surface tension of water was determined by the inventors as the reason for this controlled release. Ethanol, for example, is also a polar solvent for PAA. However, due to the decreased surface tension of ethanol with respect to water, the OSC film 120 would not be released but sticks back to the sample if the same procedure is applied. If ethanol is continuously added to DI water, a floating DNTT nanosheet sinks at an ethanol volume fraction of approx. 20%.

The floating film 160 is fished out of the water bath, as shown in FIG. 1E, by immersing in step 270 a favorable target substrate 170 in the water bath 150 and approaching the floating film 160 from underneath. The fishing of the hydrophobic floating film 160 is easier for hydrophilic ones of the target substrates 170. The angle of fishing is around 10°. Examples of such target substrates 170 include, but are not limited to, silicon wafers (including oxidized silicon wafers), glass, flexible foils, such as polyethylene terephthalate (PET), graphene, and metal dichalcogenides. Examples of the metal dichalcogenides which can be used as substrates include, but are not limited to, MoS₂, MoSe₂, WS₂, WSe₂, SnS₂. The target substrates 170 could be prefabricated with metallic conductive electrodes, such as gold or aluminium, or transparent conductive electrodes, such as ITO, IGZO, or graphene, as well as microelectronic structures.

The wetting of the hydrophilic target substrate 170 stabilizes a macroscopic water layer between the (floating) film 160 and the target substrate 170 which allows repositioning and rotating the (floating) film 160 shortly after transfer of the (floating) film 160 to the target substrate 170. It was found that the fishing with hydrophobic ones of the target substrates 170 is more challenging due to initial de-wetting of the target substrate 170. This de-wetting is similar to an attempt to deposit a water droplet on a hydrophobic surface. In this case, the edge of the hydrophobic target substrate 170 needs a contact for a few seconds to enable van der Waals adhesion of the floating film 160 to the target substrate 170. Once adhesion between the (floating) film 160 and the target substrate 170 is established, the sample can be passed out through the meniscus 155 in step 280.

In one aspect of the invention, the target substrate 170 can be pre-structured with conducting and isolation layers, vias, electrodes and the like.

In order to avoid wrinkles, the transferred nanosheets of the OSC film 120 need to be dried carefully in step 290. It was found that positioning the sample at an inclined or a substantially upright (almost vertical) position, standing on a tissue and leaning against a support, allows excess water to drain out for around 7 min efficiently from the OSC film 120, see FIG. 1F. The whole drying process including the draining of the interfacial water and the adhesion of the OSC film 120 to the target substrate 170 can be observed by eye inspection due to changes in the appearance of the sample at different stages.

The nanosheets of the OSC film 120 are as thin as 10 nm to 50 nm and can be transferred in step 295 to flexible substrates, such as but not limited to, polydimethylsiloxane (PDMS), polyethylene terephthalate (PET), and to pre-structured 2D materials on wafer substrates after clean room processes, which are commonly hydrophobic to form a transferred film 180. This is shown in FIG. 1G.

Morphology and crystallinity of the transferred films 180 were characterized by AFM and x-ray diffraction. It was found that the PAA thin film 110 promotes the formation of huge apparent grain sizes for pentacene and DNTT of 6 μm and 3 μm respectively in the OSC film 120. This confirmed that the PAA film 110 is a good growth template for the OSC film 120. The grain morphology of the OSC film 120 in the form of the nanosheet was preserved after transfer. The transfer of layered films, such as 50 nm pentacene on 50 nm C₆₀ is also possible preserving nanoscopic details.

The crystallinity of the OSC films 120 after evaporation on the PAA thin film 110 was found to be excellent. A series of Bragg peaks characteristic of a single phase was observed for both materials, DNTT and pentacene. After the transfer, the pentacene Bragg signatures change profoundly. This is quite interesting since pentacene is known to exhibit different polymorphs which can be transformed into each other in response to stress²⁷. Apparently, the meniscus assisted transfer induces sufficient stress to convert some fraction of the so-called thin film phase into the bulk (Campbell) phase. DNTT, which lacks polymorphism, does not show this effect, i.e., the crystallinity is preserved.

Small molecule crystals are well known for Davydov splitting, i.e. the reflection of grains is strongly polarization dependent²⁸. It was found that transferred pentacene OSC films 120 rastered by a polarized focused laser show pronounced Davydov splitting of the individual grains, comparable to highly ordered films grown directly on passivated substrates. Apparently, optical anisotropy of the grains is conserved upon transfer.

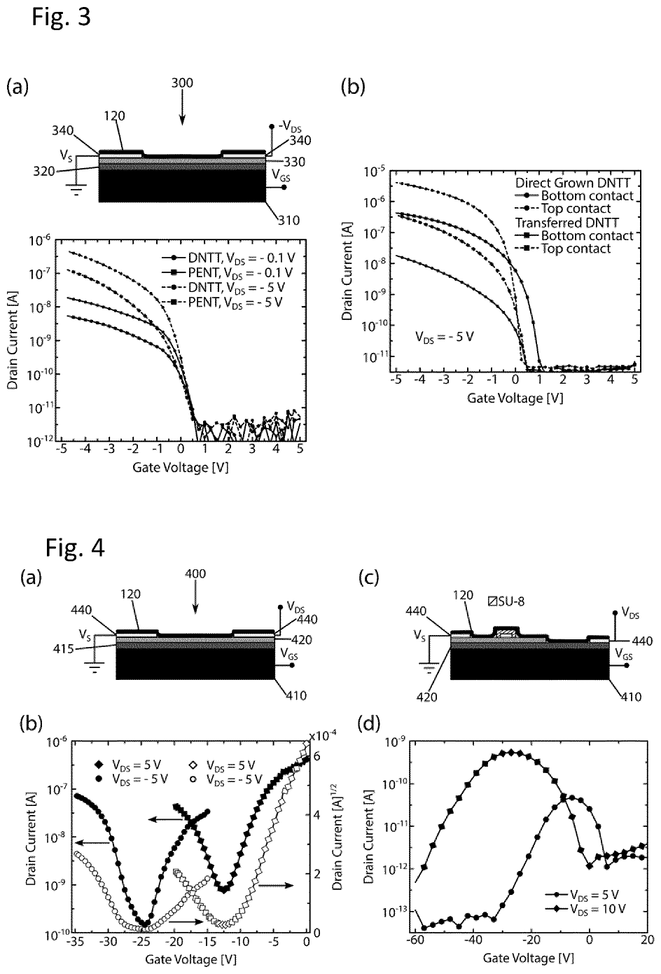

Bottom-contact, bottom-gate organic FETs 300 in inverted coplanar geometry were manufactured as sketched in FIG. 3A. The nanosheet of the OSC film 120 was transferred onto an ALD grown aluminum oxide layer 320¹ which was passivated with a tetradecylphosphonic acid SAM layer 330. The aluminum oxide layer 320 and the tetradecylphosphonic acid SAM layer 330 act as a gate dielectric. Some gold bottom contacts 340 are applied. The FETs 300 show negligible hysteresis, small threshold voltages, and on/off ratios up to 10⁵. The calculated saturation mobilities and subthreshold swings are μ=0.065 cm²/Vs, μ=0.16 cm²/Vs, 494 mV/dec, and 289 mV/dec for the OSC films 120 made from pentacene and DNTT, respectively. The FET 300 made with the DNTT OSC film 120, which did not show polymorphism during transfer, performed very weakly. This suggests that the transferred nanosheets of the OSC films 120 form a tight junction with the gold bottom contacts 340.

The performance of the FETs 300 with the DNTT OSC films 120 were investigated in in comparison to direct evaporation without transfer, see FIG. 3B. For this purpose, bottom contact (BC) and top contact (TC) direct grown (DG) FETs (DGBC and DGTC, respectively) and bottom and top contact transferred FETs (TRBC and TRTC, respectively) were fabricated. As expected, the performance of the OSC films evaporated on bottom contacts (DGBC) is poor due to the inferior growth at the contacts¹⁶. The OSC film 120 which was deposited on the bare gate dielectric (DGTC) and subsequent top contact deposition acts as benchmark; here the mobility is highest. The transferred nanosheets of the OSC film 120 described in this document bridge the enormous performance gap between the conventional bottom and top contact devices, i.e., the FETs 300 made with the transferred nanosheets of the OSC film 120 outperform conventional bottom contact devices even in bottom contact geometry confirming that the bottom contact problem is essentially a growth problem which can be overcome by the transfer process outlined in this document.

Hybrid heterojunction devices 400, such as shown in FIG. 4, are notoriously difficult to fabricate by sequential deposition since evaporation directly on clean 2D materials results in organic films of low crystallinity⁷. In the example show in FIG. 4, a chemical vapor deposition grown MoS₂ monolayer crystal 420 was deposited onto an oxidized Si substrate 410 with silicon dioxide layer 415 by PMMA assisted transfer. This deposition is a well-established procedure and is disclosed, for example in George et. Al. “Controlled growth of transition metal dichalcogenide monolayers using Knudsen-type effusion cells for the precursors”, J. Phys. Mater 2. (2019) 016001 https://doi.org/10.1088/2515-7639/aaf982, or U.S. Pat. No. 8,377,243. Source and drain gold electrodes 440 were added defining the MoS₂ FET channel width and length; typical values are W=10 μm and L=10 μm. At this stage, the hybrid heterojunction device 400 acts as unipolar n-channel FET. The p-channel of pentacene or DNTT OSC film 120 is added by the water meniscus assisted transfer method outlined in this document. To reduce leakage from the global Si back gate, a micro pin was used to scratch out the DNTT; additional e-beam steps were performed for pentacene.

The transconductance curve of the heterojunction FET devices exhibits the characteristic V-shape of ambipolar transistors, see FIG. 4A. The two asymptotic branches allow to read of the saturation behavior of the p and n-channel including mobility and threshold voltages²⁹. The DNTT heterojunction device 400 shows rather balanced mobilities of μₕ=0.18 cm²/Vs and μₑ=0.25 cm²/Vs. These values are very encouraging given that the values were measured at ambient conditions, suggesting that the hydrophobic OSC film 120 serves a dual role shielding the TMD (in this case the MoS₂ layer 420) from humidity. Similar balanced mobilities have so far only be reported for organic single crystals deposited on 2D materials⁸.

The ambipolar currents are shown in the bottom half of FIG. 4A, i.e., the characteristic of the dip in the transconductance curve. This is the interesting part, where electrons and holes are both present in the device interacting via recombination. For ideal devices, the current in the ambipolar region can be expressed as the sum of an electron and hole current³⁰:

$$\vert {I}_{ds} \vert = \frac{{WC}_{i}}{2 L} \{ {{μ}_{e} ( {V}_{g} - {V}_{Th , e} )}^{2} + {{μ}_{h} ( {V}_{ds} - ( {V}_{g} - {V}_{Th , h} ) )}^{2} \} \qquad Eq . ( 1 )$$

A current of I_{ds}=100 pA for V_{ds}=+/−5V was measured. According to Eq. 1, the ambipolar current should drop to zero in the dip, at least for such moderate drain voltages. Instead, the heterojunction device 400 is operating in a subthreshold region where the behavior is controlled by trap states and the picture of an electron and hole accumulation zone meeting at the recombination point fails. The calculated subthreshold swings for the TMD MoS₂ layer 420 are around 2.31 V/dec which is typical for the small capacitance used here (C=38.4 nF/cm²) amplifying the influence of subthreshold traps (N_{t,sub}=9.16×10¹² eV⁻¹ cm⁻²) and deep traps associated with threshold shift. To verify that the OSC/TMD heterojunction device 400 allows for recombination of electrons and holes, a so-called anti-ambipolar geometry was employed. Here the ambipolar currents were reinforced by physical insulation of the OSC film 120 and the TMD MoS₂ layer 420 from the source and drain contact 440, respectively, cf. FIG. 4B. As expected, this changes the transconductance drastically, i.e., the transconductance dip transforms to a maximum as the fingerprint of ambipolar behavior with a signal to noise ratio of 10³. This confirms that indeed a 2D/3D heterostructure junction formed, i.e., the transferred OSC film 120 is in tight contact with the TMD MoS₂ layer 420.

In a further aspect of the invention, was also possible to create and transfer an OSC film 120 that comprises two different small molecules deposited layer by layer. This was demonstrated by evaporating 50 nm of pentacene onto the PAA thin film 110 and followed by an evaporation of 50 nm C₆₀ on pentacene. The resulting bilayer nanosheet forming the OSC film 120 was transferred using the method described in steps 270-295. It was found that PAA is a good template for pentacene thin film growth, where pentacene is a good template to grow a film of C₆₀. The grains of C₆₀ can grow on the terraces of pentacene grains and it is conserved after transfer. These bilayers can be used for organic p-n junctions or ambipolar transistors

### Methods

Organic Deposition. Si/SiO₂ substrates were sonicated at 60° C. for 5 min and 10 min in acetone and isopropanol then followed by 10 min distilled water at 60° C. The surface was activated by O₂ plasma treatment (10 standard cubic centimeters per second) at 50 W for 5 min for polyacrylic acid (PAA) spinning. A thin (approx. 50 nm) sacrificial layer of PAA (volume fraction 2.5%, filtered by a 0.22 μm pore size syringe filter) was spin coated (60 s for 4000 rpm) onto the wafer. The substrates were immediately loaded into an UHV chamber and 50 nm thick pentacene or DNTT film was evaporated at a base pressure of middle 10⁻⁸ mbar at room temperature and 60° C.

AFM and X-Ray measurements. AFM images are recorded by a Bruker Dimensional Icon. The deposition rates and substrate temperatures for the films used in the AFM measurements are 0.02 Å/s evaporation rate at room temperature for pentacene and at 0.1 Å/s at 60° C. for DNTT. For X-Ray measurements in house X-ray setup was used with Mo source and a monochromatic beam in reflection geometry.

Device Fabrication. For organic FETs, the Si/AlOₓ/SAM substrates were patterned by a shadow polyimide mask (Cadilac Laser GmbH). The organic OSC films 120 were laminated by meniscus assisted transfer. For the hybrid FETs, CVD grown MoS₂ was transferred on a bottom gate structure of Si and SiO₂ (300 nm for pentacene, 90 nm for DNTT) by a PMMA assisted wet transfer. The electrodes were patterned by e-beam or photo lithography for pentacene and DNTT based devices. For all of the FETs the OSC films 120 were evaporated with 0.1 Å/s at room temperature for pentacene and 60° C. for DNTT devices and transferred directly after evaporation.

Electrical Characterization. A probe station in dark ambient conditions connected to a Keithley 2612B source measure unit was used for organic FETs and DNTT/MoS₂ hybrid transistors.

### Device Fabrication

For organic FET's, AlOₓ on a doped p-type silicon wafer was deposited by atomic layer deposition and its thickness is verified by ellipsometer as 33 nm. For the SAM modification, the substrates are immersed into a 1 mM solution of tetradecylphosphonic acid (Sigma-Aldrich) in isopropanol for 3 hours directly after plasma process. Afterwards, the substrates are gently washed with isopropanol and annealed at 130° for 1 hour. After cooling, the substrates were (2 min) sonicated shortly in isopropanol to remove excess layers. 5 nm of titanium and 30 nm of gold was evaporated by e-beam evaporator through a shadow polyimide mask (Cadilac Laser GmbH). Then, the organic nanosheets were laminated by meniscus assisted transfer.

For the hybrid FET's the CVD grown MoS₂ layer 420 was transferred on a bottom gate structure of Si and SiO₂ (90 nm) by PMMA assisted wet transfer. Then, the electrodes 440 were patterned by e-beam or photo lithography for the pentacene and DNTT based heterojunction devices 400, respectively. Depending on the type of the heterojunction device 400, the lithography steps are changed: Two electrodes 440 were patterned on the MoS₂ layer 420 as source and drain electrodes with a defined channel width and length and then the OSC film 120 was laminated for the ambipolar structure. For the anti-ambipolar structure, one of the electrodes 440 was patterned on the MoS₂ layer 420 and the other one of the electrodes 440 was patterned on the SiO₂ layer 420. Then, the electrode 440 on the MoS₂ layer 420 was covered with SU-8 photoresist 450 to prevent the contact with the OSC thin film 120 by an additional lithography step. Afterwards, the OSC film 120 was laminated by meniscus assisted transfer on the devices for hybridization.

For all FET's the nanosheets of the OSC film 120 were evaporated with 0.1 Å/s at room temperature for pentacene and 60° C. for DNTT devices and transferred right after evaporation.

### Acknowledgements

The inventors acknowledge financial support by EU within FLAG-ERA JTC 2017 managed Deutsche Forschungsgemeinsschaft (DFG) under contract nr. NI 632/6-1 and TU 149/9-1. Bert Nickel acknowledges support from the Bavarian State Ministry of Science, Research and Arts through the grant “Solar Technologies go Hybrid (SolTech)”

### REFERENCES

1 Klauk, H., Zschieschang, U., Pflaum, J. & Halik, M. Ultralow-power organic complementary circuits. Nature 445, 745-748, doi:10.1038/nature05533 (2007).
2 Yamamoto, T. & Takimiya, K. Facile Synthesis of Highly π-Extended Heteroarenes, Dinaphtho[2,3-b:2′,3′-f]chalcogenopheno[3,2-b]chalcogenophenes, and Their Application to Field-Effect Transistors. Journal of the American Chemical Society 129, 2224-2225, doi:10.1021/ja068429z (2007).
3 Collins, S. D., Ran, N. A., Heiber, M. C. & Nguyen, T.-Q. Small is Powerful: Recent Progress in Solution-Processed Small Molecule Solar Cells. Advanced Energy Materials 7, 1602242, doi:https://doi.org/10.1002/aenm.201602242 (2017).
4 Leung, L. M., Lo, W. Y., So, S. K., Lee, K. M. & Choi, W. K. A High-Efficiency Blue Emitter for Small Molecule-Based Organic Light-Emitting Diode. Journal of the American Chemical Society 122, 5640-5641, doi:10.1021/ja000927z (2000).
5 Radisavljevic, B., Radenovic, A., Brivio, J., Giacometti, V. & Kis, A. Single-layer MoS2 transistors. Nature Nanotechnology 6, 147-150, doi:10.1038/nnano.2010.279 (2011).
6 Larentis, S., Fallahazad, B. & Tutuc, E. Field-effect transistors and intrinsic mobility in ultra-thin MoSe2 layers. Applied Physics Letters 101, 223104, doi:10.1063/1.4768218 (2012).
7 Jariwala, D. et al. Hybrid, Gate-Tunable, van der Waals p-n Heterojunctions from Pentacene and MoS2. Nano Letters 16, 497-503, doi:10.1021/acs.nanolett.5b04141 (2016).
8 He, X., Chow, W., Liu, F., Tay, B. & Liu, Z. MoS2/Rubrene van der Waals Heterostructure: Toward Ambipolar Field-Effect Transistors and Inverter Circuits. Small 13, 1602558, doi:10.1002/sm11.201602558 (2017).
9 Zhang, X., Dong, H. & Hu, W. Organic Semiconductor Single Crystals for Electronics and Photonics. Advanced Materials 30, 1801048, doi:https://doi.org/10.1002/adma.201801048 (2018).
10 Hack, M., Brown, J. J., Mahon, J. K., Kwong, R. C. & Hewitt, R. Performance of high-efficiency AMOLED displays. Journal of the Society for Information Display 9, 191-195 (2001).
11 Horowitz, G. Organic Field-Effect Transistors. Advanced Materials 10, 365-377, doi:https://doi.org/10.1002/(SICI)1521-4095(199803)10:5<365::AID-ADMA365>3.0.CO; 2-U (1998).
12 Sun, J. et al. 2D—Organic Hybrid Heterostructures for Optoelectronic Applications. Advanced Materials 31, 1803831, doi:10.1002/adma.201803831 (2019).
13 Liu, X. & Hersam, M. C. Interface characterization and control of 2D materials and heterostructures. Advanced Materials 30, 1801586 (2018).
14 Gobbi, M., Orgiu, E. & Samori, P. When 2D materials meet molecules: opportunities and challenges of hybrid organic/inorganic van der Waals heterostructures. Advanced Materials 30, 1706103 (2018).
15 Ruiz, R. et al. Pentacene ultrathin film formation on reduced and oxidized Si surfaces. Physical Review B 67, 125406, doi:10.1103/PhysRevB.67.125406 (2003).
16 Noever, S. J. et al. Transferable Organic Semiconductor Nanosheets for Application in Electronic Devices. Advanced Materials 29, 1606283, doi:10.1002/adma.201606283 (2017).
17 Borchert, J. W. et al. Small contact resistance and high-frequency operation of flexible low-voltage inverted coplanar organic transistors. Nature Communications 10, 1119, doi:10.1038/s41467-019-09119-8 (2019).
18 Park, H. J. et al. Hybrid characteristics of MoS2 monolayer with organic semiconducting tetracene and application to anti-ambipolar field effect transistor. ACS applied materials & interfaces 10, 32556-32566 (2018).
19 Park, C.-J. et al. Photovoltaic Field-Effect Transistors Using a MoS2 and Organic Rubrene van der Waals Hybrid. ACS Applied Materials & Interfaces 10, 29848-29856, doi:10.1021/acsami.8b11559 (2018).
20 Kim, J.-K. et al. Trap-mediated electronic transport properties of gate-tunable pentacene/MoS2 p-n heterojunction diodes. Scientific Reports 6, 36775, doi:10.1038/srep36775 (2016).
21 Lee, W. H. et al. Surface-Directed Molecular Assembly of Pentacene on Monolayer Graphene for High-Performance Organic Transistors. Journal of the American Chemical Society 133, 4447-4454, doi:10.1021/ja1097463 (2011).
22 Bettis Homan, S. et al. Ultrafast Exciton Dissociation and Long-Lived Charge Separation in a Photovoltaic Pentacene—MoS2 van der Waals Heterojunction. Nano Letters 17, 164-169, doi:10.1021/acs.nanolett.6b03704 (2017).
23 Liu, F. et al. Van der Waals p-n junction based on an organic-inorganic heterostructure. Advanced Functional Materials 25, 5865-5871 (2015).
24 Dong, J. et al. Configuration-dependent anti-ambipolar van der Waals p-n heterostructures based on pentacene single crystal and MoS 2. Nanoscale 9, 7519-7525 (2017).
25 Di, C.-a. et al. Effect of dielectric layers on device stability of pentacene-based field-effect transistors. Physical Chemistry Chemical Physics 11, 7268-7273, doi:10.1039/B902476J (2009).
26 Eid, K. F., Panth, M. & Sommers, A. D. The physics of water droplets on surfaces: exploring the effects of roughness and surface chemistry. European Journal of Physics 39, 025804, doi:10.1088/1361-6404/aa9cba (2018).
27 Murakami, Y. et al. Microstructural Study of the Polymorphic Transformation in Pentacene Thin Films. Physical Review Letters 103, 146102, doi:10.1103/PhysRevLett.103.146102 (2009).
28 Cocchi, C., Breuer, T., Witte, G. & Draxl, C. Polarized absorbance and Davydov splitting in bulk and thin-film pentacene polymorphs. Physical Chemistry Chemical Physics 20, 29724-29736, doi:10.1039/C8CP06384B (2018).
29 Horowitz, G., Hajlaoui, R., Bouchriha, H., Bourguiga, R. & Hajlaoui, M. The Concept of “Threshold Voltage” in Organic Field-Effect Transistors. Advanced Materials 10, 923-927, doi:https://doi.org/10.1002/(SICI)1521-4095(199808)10:12<923::AID-ADMA923>3.0.CO; 2-W (1998).
30 Zaumseil, J. & Sirringhaus, H. Electron and Ambipolar Transport in Organic Field-Effect Transistors. Chemical Reviews 107, 1296-1323, doi:10.1021/cr0501543 (2007).

### REFERENCE NUMERALS

100 Substrate
110 Polyacrylic acid (PAA) thin film
120 Organic semiconductor (OSC) film
130 Water Droplet
140 Glass slide
150 Water bath
155 Meniscus
160 Floating film
170 Target substrate
180 Transferred film
300 Field effect transistor
310 Substrate
320 aluminum oxide layer
330 tetradecylphosphonic acid SAM layer
340 Gold bottom contacts
400 Hybrid heterojunction device
410 Substrate
415 Silicon dioxide
420 MoS₂ layer
440 Electrodes
450 Photoresist

1. A method of transferring a semiconductor film (120) from a first substrate (100) to a target substrate (170) comprising: coating (210) a water-soluble thin film (110) onto the first substrate (100); growing (220) a layer of the semiconductor film (120) onto the water-soluble thin film (100); placing (230) the water-soluble thin film (110) in contact with water (130) to enable dissolution of the water-soluble thin film (110); floating (250) the semiconductor film (120) on a meniscus (155) of water; placing one end of the floating semiconductor film (120) in contact with the target substrate (170); and passing (280) the target substrate (170) through the meniscus at an angle.

2. The method of claim 1, further comprising drying (290) by placing the target substrate (170) in an inclined or a substantially upright position to enable drying of the semiconductor film (120).

3. The method of claim 1, wherein the placing (230) of the water-soluble thin film (110) in contact with water comprises placing water on a surface adjacent to the water-soluble thin film (110).

4. The method claim 1, wherein the floating (250) of the semiconductor film (120) comprises contacting the first substrate (100) to the meniscus (155) of the water.

5. The method of claim 1, wherein the water-soluble thin film (110) comprises one of a polyacrylic acid thin film, poly(sodium-4-styrene sulfonate) (PSSNa) thin film, or a polyvinyl alcohol (PVA) thin film.

6. The method of claim 1, wherein the semiconductor film (120) is made of a material with a molecular weight of less than 1000 Daltons.

7. The method of claim 1, wherein the semiconductor film (120) is an organic semiconductor film, such as pentacene or DNTT and functionalized derivatives thereof, or fullerene.

8. The method of claim 1, wherein the target substrate (170) comprises one of a transition metal dichalcogenide layer, or a pre-structured substrate.

9. The method of claim 8, wherein the transition metal dichalcogenide layer is a MOS2 monolayer crystal (410).

10. The method of claim 1, wherein the target substrate (170) is a passivated aluminum oxide layer (320).

11. The method of claim 10, wherein passivation is a tetradecylphosphonic acid SAM layer.

12. The method of claim 8, further comprising application of contacts (340, 440) to the semiconductor film (120). 13. A heterojunction device (300, 400) manufactured by the method of claims 1 to 12.
